(19) United States
(12) Patent Application Publication
(10) Pub. No.: US 2026/0255899 A1
(43) Pub. Date: Aug. 27, 2026

(54) SEMICONDUCTOR STRUCTURE WITH REDUCED GATE CONTACT RESISTANCE AND METHOD FOR MANUFACTURING THE SAME

(71) Applicant: TAIWAN SEMICONDUCTOR MANUFACTURING COMPANY, LTD., Hsinchu (TW)

(72) Inventors: Peng-Hsuan CHIANG, Hsinchu (TW); Po-Chin CHANG, Hsinchu (TW); Chia-Hung CHU, Hsinchu (TW); Sung-Li WANG, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 19/064,895

(22) Filed: Feb. 27, 2025

(51) Int. Cl. H01L 21/311; H10D 30/00; H10D 30/01; H10D 62/10; H10D 64/23; H10D 64/66; H10D 84/01; H10D 84/83

(52) U.S. Cl. CPC H10P 50/285; H10D 30/0191; H10D 62/102; H10D 62/121; H10D 62/124; H10D 64/256; H10D 64/665; H10D 64/667; H10D 84/0149; H10D 30/502; H10D 84/832

(57) ABSTRACT

A method for manufacturing a semiconductor structure includes: forming a base structure on a substrate, the base structure including a gate electrode and a gate dielectric layer covering the gate electrode; forming a via opening extending from an upper surface of the base structure to expose the gate dielectric layer; performing a non-plasma etching process on the gate dielectric layer through the via opening until the via opening penetrates the gate dielectric layer to expose a portion of the gate electrode; and forming a conductive cap portion on the portion of the gate electrode, so as to prevent the portion of the gate electrode from being exposed through the via opening, the non-plasma etching process and formation of the conductive cap portion are performed without breaking vacuum.

### BACKGROUND

At present, integrated circuits (ICs) are widely used in consumer electronics products (such as mobile phones), high performance computing applications, and automotive electronics products. Scaling down the size of semiconductor devices leads to decrease in chip size, which is in accordance to Moore's Law. However, decrease in the chip size incurs problems, such as increased resistance and parasitic effects, causing limitation in device performance. In order to allow the electronics products to have high device performance, various approaches are being continuously developed for optimizing the transistors in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 18B illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

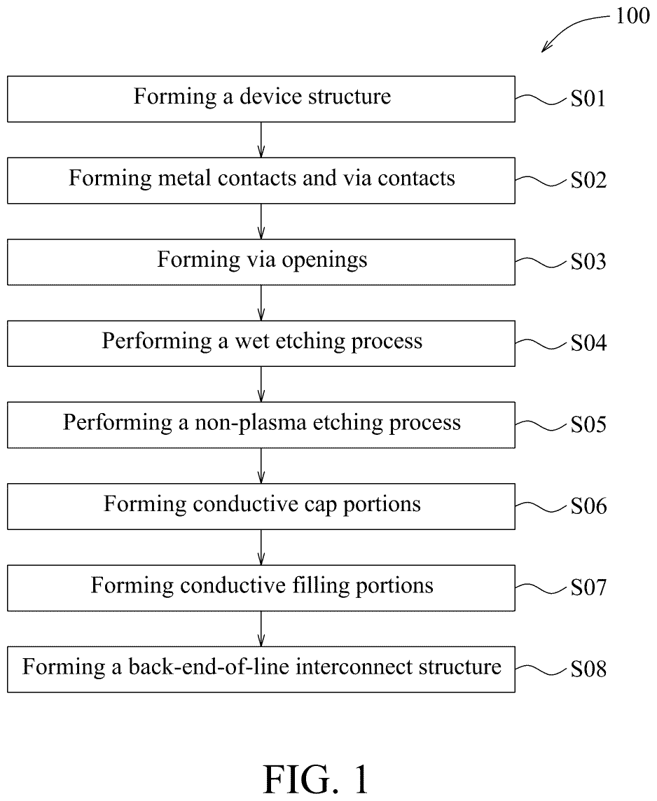

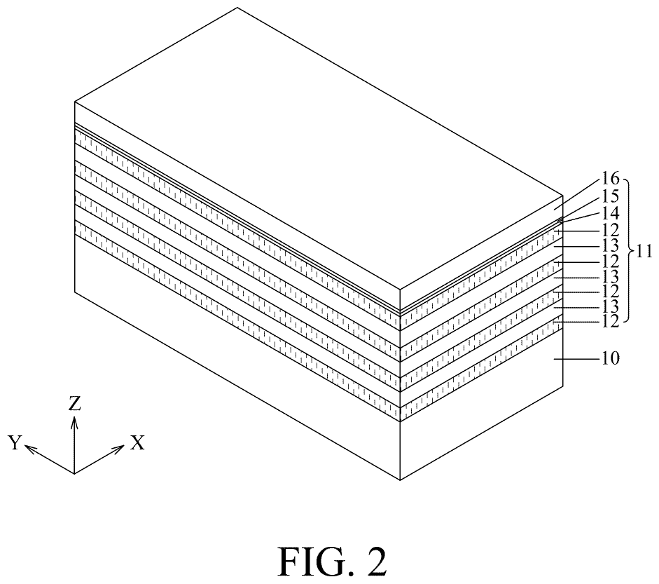

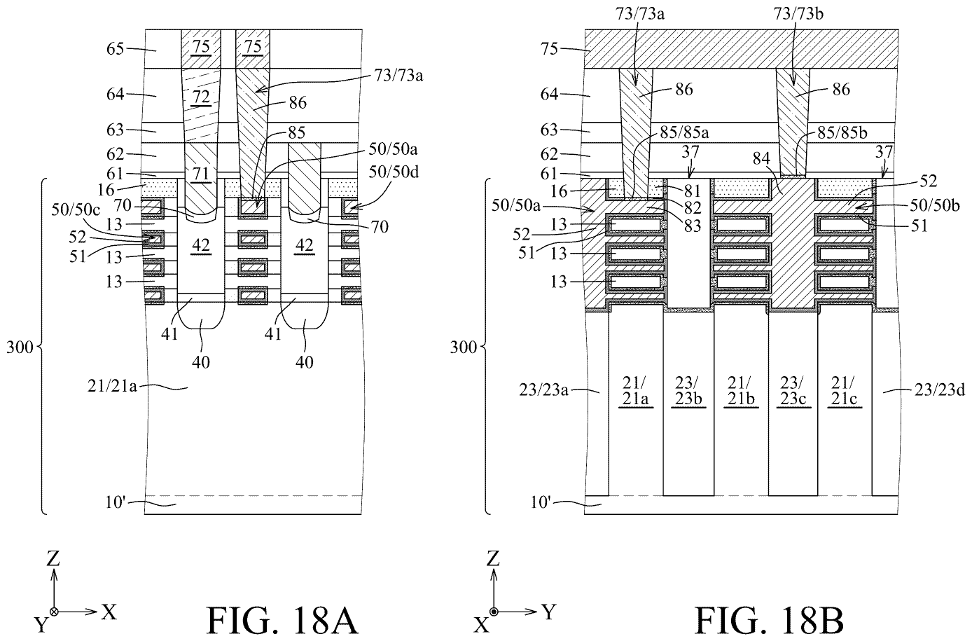

FIG. 1 is a flow diagram illustrating a method 100 for manufacturing a semiconductor structure (for example, but not limited to, a semiconductor structure 200 shown in FIGS. 18A and 18B) in accordance with some embodiments. The method 100 may include steps S01 to S08. FIGS. 2 to 18B illustrate schematic views of intermediate stages of the method 100 in accordance with some embodiments. Some repeating structures are omitted in FIGS. 2 to 18B for the sake of brevity. Additional steps can be provided before, after or during the method 100, and some steps in the method 100 may be modified, replaced, or eliminated without departure from the spirit and scope of the present disclosure.

As shown in FIGS. 18A and 18B, the semiconductor structure 200 includes a device structure 300 and gate contacts 73 (including the gate contacts 73a, 73b). Each of the gate contacts 73 is connected to a corresponding gate electrode 52 of the device structure 300. In some embodiments, as shown in FIG. 18B, the device structure 300 is configured to a forksheet structure, but is not limited thereto. In some other embodiments not shown herein, the device structure may be configured as a gate-all-around (GAA) structure, in which four side surfaces of each channel are surrounded by a gate electrode. Alternatively, the device structure may be configured as a complementary field-effect transistor (CFET) structure which includes a lower gate-all-around field-effect transistor (GAAFET) and an upper GAAFET sequentially formed over a substrate.

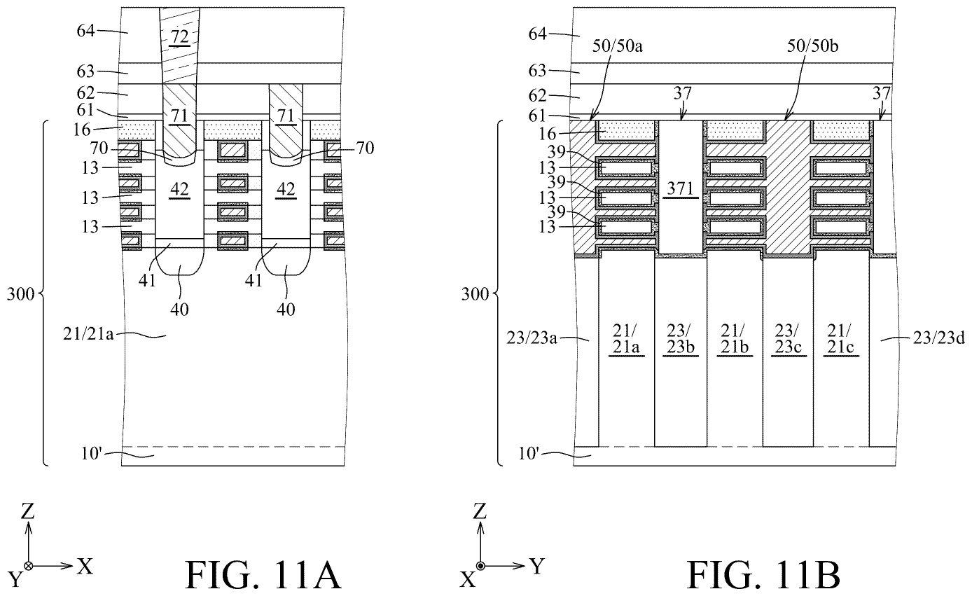

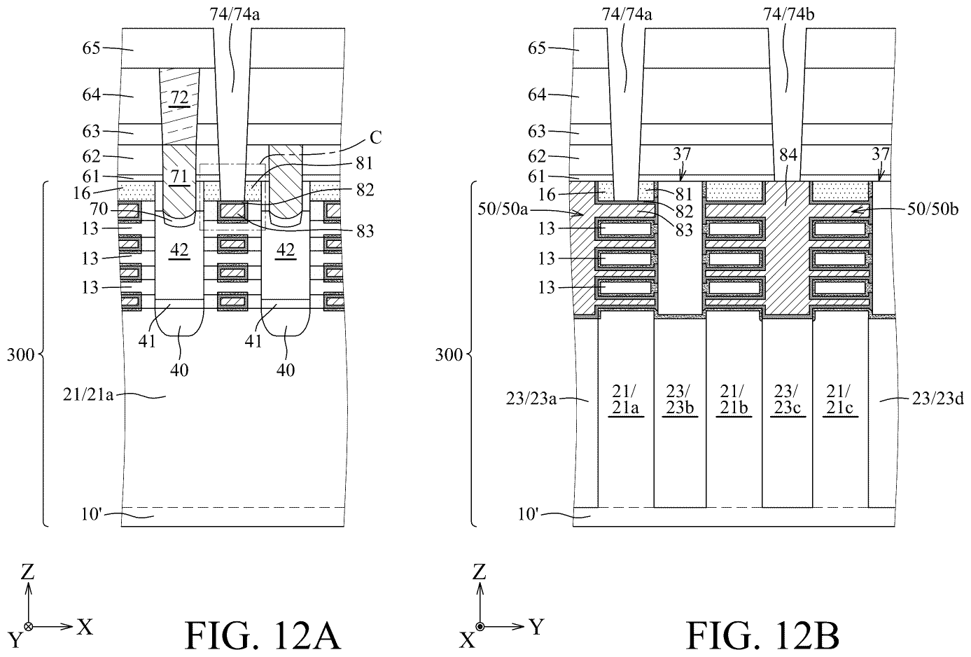

FIGS. 2 to 10B illustrate the intermediate stages in formation of the device structure 300 (step S01), and FIGS. 11A to 17B illustrate the intermediate stages in formation of a middle-end-of-line (MEOL) interconnect structure (including the gate contacts 73) on the device structure 300 in accordance with some exemplary embodiments. In the present disclosure, formation of the gate contacts 73 involves a non-plasma etching process and an in-situ deposition process, such that a contact resistance between each of the gate contacts 73 and the corresponding gate electrode 52 may be effectively reduced, thereby significantly enhancing the device performance of the semiconductor structure 200. It is appreciated that a gate contact may be formed on a GAAFET in a GAA structure or on an upper GAAFET in a CFET structure in a manner similar to that as described with reference to FIGS. 12A to 17B after appropriate modifications.

FIG. 2 is a schematic perspective view illustrating a starting substrate 10 and a lamination structure 11 formed on the starting substrate 10 in accordance with some embodiments.

In some embodiments, the starting substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the starting substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the starting substrate 10 may be formed with an n-type well having an n-type conductivity and a p-type well having a p-type conductivity. Each of the n-type well and the p-type well may be formed by introducing an n-type impurity or a p-type impurity into the starting substrate 10 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the starting substrate 10 may be configured as a semiconductor-on-insulator substrate. Other suitable materials and configurations for the starting substrate 10 are within the contemplated scope of the present disclosure.

The lamination structure 11 may include sacrificial layers 12, channel layers 13 disposed to alternate with the sacrificial layers 12 in a Z direction, and a protective layer 16 disposed on an uppermost one of the sacrificial layers 12 opposite to an uppermost one of the channel layers 13.

Each of the sacrificial layers 12 is made of a first semiconductor material, and each of the channel layers 13 is made of a second semiconductor material that is different from the first semiconductor material, so that the sacrificial layers 12 may be selectively removed in a subsequent step, and the channel layers 13 are substantially intact due to different etching selectivity ratios. Possible semiconductor materials suitable for the sacrificial layers 12 and the channel layers 13 are similar to those for the starting substrate 10, and thus the details thereof are omitted for the sake of brevity. In some embodiments, the sacrificial layers 12 are made of silicon germanium, and the channel layers 13 are made of silicon. Other materials suitable for the sacrificial layers 12 and the channel layers 13 are within the contemplated scope of the present disclosure. In some embodiments, each of the sacrificial layers 12 has a thickness ranging from about 4 nm to about 14 nm. In some embodiments, each of the channel layers 13 has a thickness ranging from about 3 nm to about 9 nm, or ranging from about 5 nm to about 8 nm.

The protective layer 16 is made of a dielectric material. In some embodiments, the protective layer 16 is made of a nitride-based material which includes silicon nitride, silicon oxynitride, silicon carbon nitride, silicon oxycarbon nitride, other suitable nitride-based materials with low dielectric constant (k), or combinations thereof. In some embodiments, the protective layer 16 has a thickness ranging from about 3 nm to about 9 nm, or ranging from about 5 nm to about 8 nm.

In some embodiments, the lamination structure 11 further includes a silicon layer 14 and a silicon oxide layer 15 which are disposed between the protective layer 16 and the uppermost one of the sacrificial layers 12 so as to improve an adhesion between the protective layer 16 and the uppermost one of the sacrificial layers 12. The silicon oxide layer 15 and the silicon layer 14 are respectively in contact with the the protective layer 16 and the uppermost one of the sacrificial layers 12.

In some embodiments, the lamination structure 11 is formed by chemical vapor deposition (CVD), atomic layer deposition (ALD), an epitaxial growth process (such as molecular-beam epitaxy (MBE), selective area epitaxy (SAE), etc.), or other suitable deposition techniques.

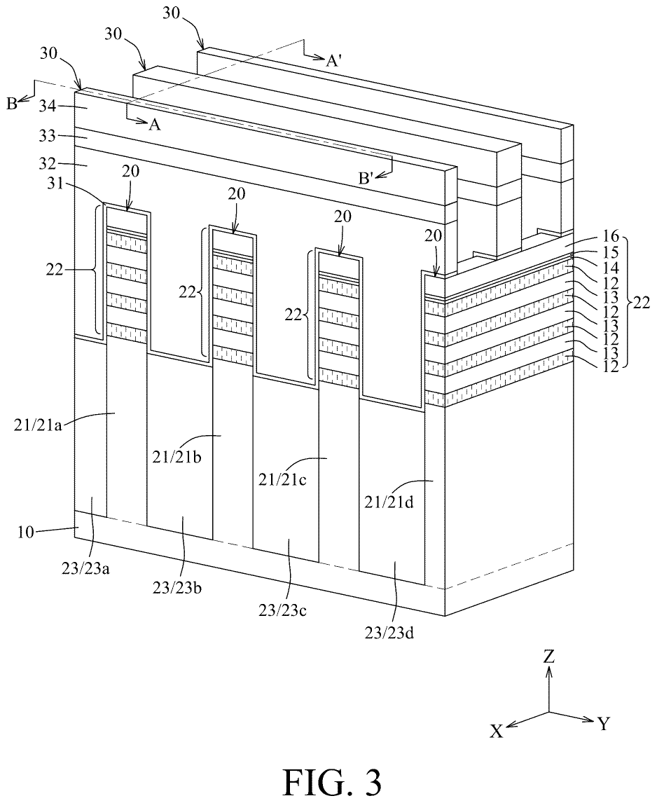

Referring to FIG. 3, the lamination structure 11 and the starting substrate 10 is patterned using a photolithography process followed by an etching process, so as to form trenches (not shown) extending into the starting substrate 10. The lamination structure 11 is formed into film stacks 22, and the starting substrate 10 is formed into protrusions 21 (including the protrusions 21a, 21b, 21c, 21d) on a substrate 10'. The film stacks 22 are respectively disposed on the protrusions 21. The protrusions 21 and the film stacks 22 collectively constitute fin structures 20, each of which includes one of the protrusions 21 and a respective one of the film stacks 22.

The fin structures 20 extend lengthwise along an X direction transverse to the Z direction, and two adjacent ones of the fin structures 20 are spaced apart from each other in a Y direction transverse to each of the X and Z directions. The number of the fin structures 20 may vary according to practical applications and is not limited the number exemplarily shown in FIG. 3. In some embodiments, the X, Y and Z directions are perpendicular to each other.

Next, still referring to FIG. 3, isolation structures 23 (including the isolation structures 23a, 23b, 23c, 23d) are respectively formed in the trenches, such that each of the isolation structures 23 is disposed to separate two corresponding adjacent ones of the protrusions 21. An upper part of each of the protrusions 21 is exposed from two corresponding adjacent ones of the isolation structures 23. In some embodiments, the isolation structures 23 may each be a shallow trench isolation (STI), a deep trench isolation (DTI), or other suitable structures. In some embodiments, the isolation structures 23 may include silicon oxide, silicon nitride, silicon oxynitride, silicon oxide formed from tetraethoxysilane (TEOS), other low-k dielectric materials, or combinations thereof. Other insulating materials suitable for the isolation structures 23 are within the contemplated scope of the present disclosure.

In some embodiments, formation of the isolation structures 23 may include (i) forming an isolation layer (not shown) over the substrate 10′ and the fin structures 20 to fill the trenches, (ii) performing a planarization process (for example, but not limited to, chemical mechanism polishing (CMP)) on the isolation layer to form isolation regions (not shown), and (iii) recessing the isolation regions until the upper part of each of the protrusions 21 is exposed.

Then, dummy structures 30 are formed. Each of the dummy structures 30 extends lengthwise along the Y direction over the fin structures 20 and the isolation structures 23. The dummy structures 30 are spaced apart from each other in the X direction.

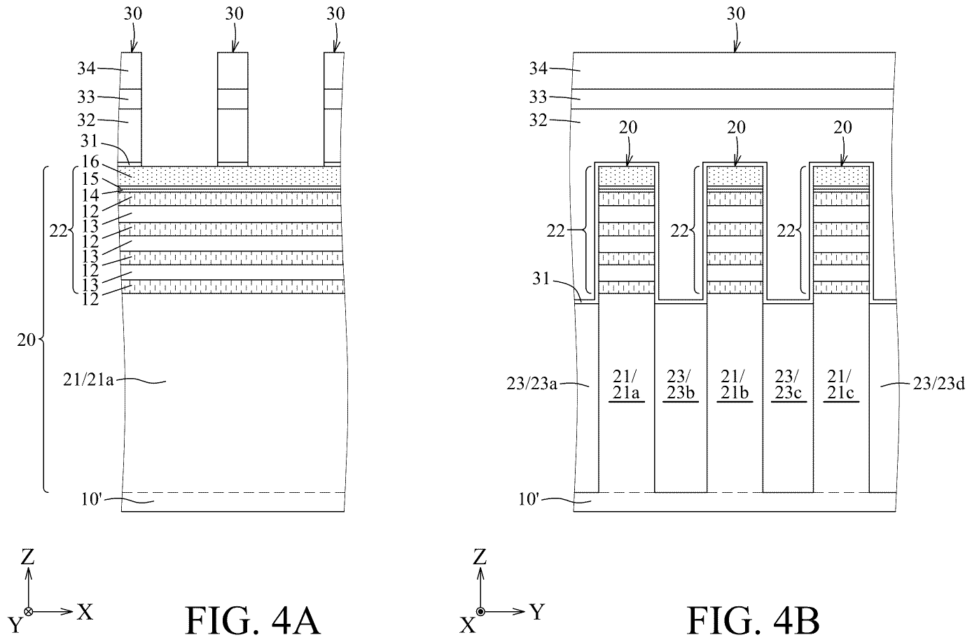

Each of the dummy structures 30 includes a dummy dielectric 31, a dummy gate 32, a polish stop layer 33, and a hard mask 34. The dummy dielectric 31 is disposed over the fin structures 20 and the isolation structures 23. The dummy gate 32, the polish stop layer 33, and the hard mask 34 are sequentially formed on the dummy dielectric 31. In some embodiments, the dummy dielectric 31 may include silicon oxide, silicon nitride, silicon oxynitride, high dielectric constant (k) materials, other suitable dielectric materials, or combinations thereof. In some embodiments, the dummy gate 32 may include polycrystalline silicon, single crystalline silicon, amorphous silicon, or combinations thereof. The polish stop layer 33 and the hard mask 34 are made of different materials. In some embodiments, possible materials suitable for the polish stop layer 33 and the hard mask 34 may include silicon nitride, silicon oxide, silicon oxynitride, or combinations thereof. Other materials suitable for the dummy structures 30 are within the contemplated scope of the present disclosure. In some embodiments, formation of the dummy structures 30 may include (i) sequentially forming a first dummy layer (not shown) for forming the dummy dielectric 31 and a second dummy layer (not shown) for forming the dummy gate 32 over the fin structures 20 and the isolation structures 23 by CVD, ALD, physical vapor deposition (PVD), or other suitable deposition techniques, (ii) performing a planarization process (e.g., CMP) to obtain a planar upper surface of the second dummy layer, (iii) sequentially forming a third dummy layer (not shown) for forming the polish stop layer 33 and a fourth dummy layer (not shown) for forming the hard mask 34 on the planarized second dummy layer, and (iv) patterning the first dummy layer, the planarized second dummy layer, the third dummy layer, and the fourth dummy layer using a photolithography process followed by an etching process, thereby obtaining the dummy structures 30. FIG. 4A is a schematic sectional view (an X-cut view) taken along line A-A′ of FIG. 3, and FIG. 4B is a schematic sectional view (a Y-cut view) taken along line B-B′ of FIG. 3.

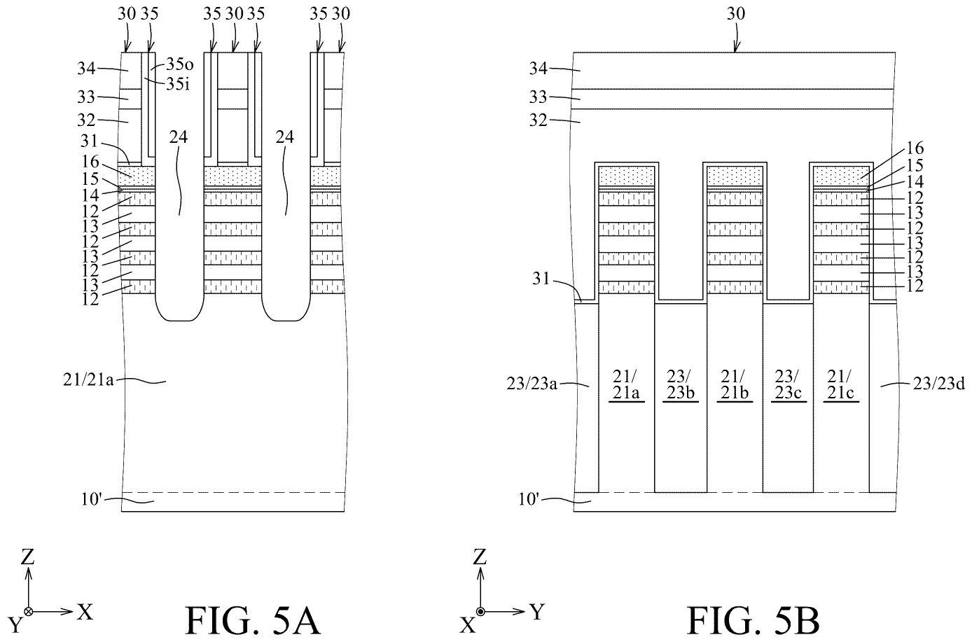

Referring to FIGS. 5A and 5B, pairs of gate spacers 35 are formed. Each pair of the gate spacers 35 are respectively disposed at two opposite sides of a respective one of the dummy structures 30 in the X direction.

In some embodiments, formation of the gate spacers 35 includes: forming a spacer layer (not shown) to cover the dummy structures 30, exposed portions of the fin structures 20 and the isolation structures 23 by CVD, ALD, PVD, or other suitable deposition techniques; and performing an anisotropic etching process on the spacer layer to remove horizontal portions of the spacer layer, while leaving vertical portions of the spacer layer. The vertical portions of the spacer layer remain at side surfaces of the gate structures 30 and serve as the gate spacers 35.

In some embodiments, each of the gate spacers 35 includes or is made of, for example, but not limited to, silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, a porous oxide material, other suitable low dielectric constant (low-k) materials, or combinations thereof. In some embodiments, each of the gate spacers 35 may be configured as a single layer structure or a multi-layered structure. For example, as shown in FIG. 5A, each of the gate spacers 35 is formed as a bi-layered structure including an outer sub-layer 35o and an inner sub-layer 35i which is disposed between the outer sub-layer 35o and a corresponding one of the dummy structures 30. The outer sub-layer 35o has a dielectric constant value (k-value) that is greater than a k-value of the inner sub-layer 35i. The k-value of each of the outer and inner sub-layers 35o, 35i may be adjusted by varying the proportions of silicon, oxygen, carbon, nitrogen, and/or other elements (such as hydrogen) in the dielectric material thereof.

Next, still referring to FIGS. 5A and 5B, each of the film stacks 22 are patterned to form source/drain recesses 24 by an etching process (for example, but not limited to, dry etching, wet etching, or a combination thereof). In some embodiments, each of the source/drain recesses 24 may extend into a corresponding one of the protrusions 21 by a predetermined depth. Accordingly, the channel layers 13 and the protective layer 16 in each of the film stacks 22 (see FIG. 4A) are formed into channel stacks. Each of the channel stacks includes channel portions (still denoted by the reference numeral 13), and a protection portion (still denoted by the reference numeral 16) disposed above an uppermost one of the channel portions 13.

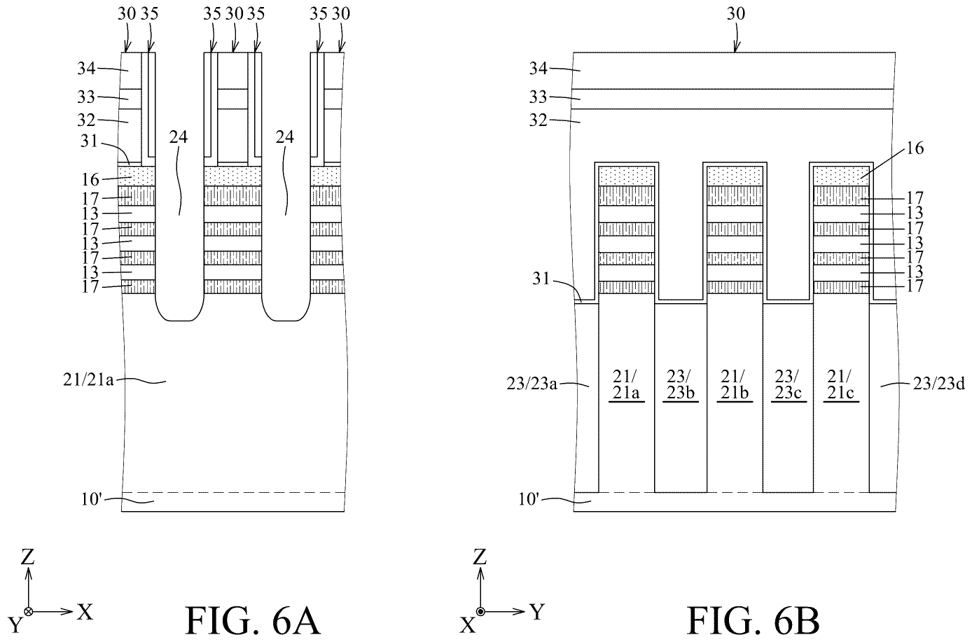

Referring to FIGS. 6A and 6B, the remaining portions of the sacrificial layers 12, the silicon layer 14, and the silicon oxide layer 15 (see FIGS. 5A and 5B) are replaced with dielectric interposers 17 by suitable etching and deposition techniques. In some embodiments, the dielectric interposers 17 may include silicon oxide, silicon oxynitride, silicon oxycarbide, silicon oxycarbon nitride, or other suitable removable dielectric materials.

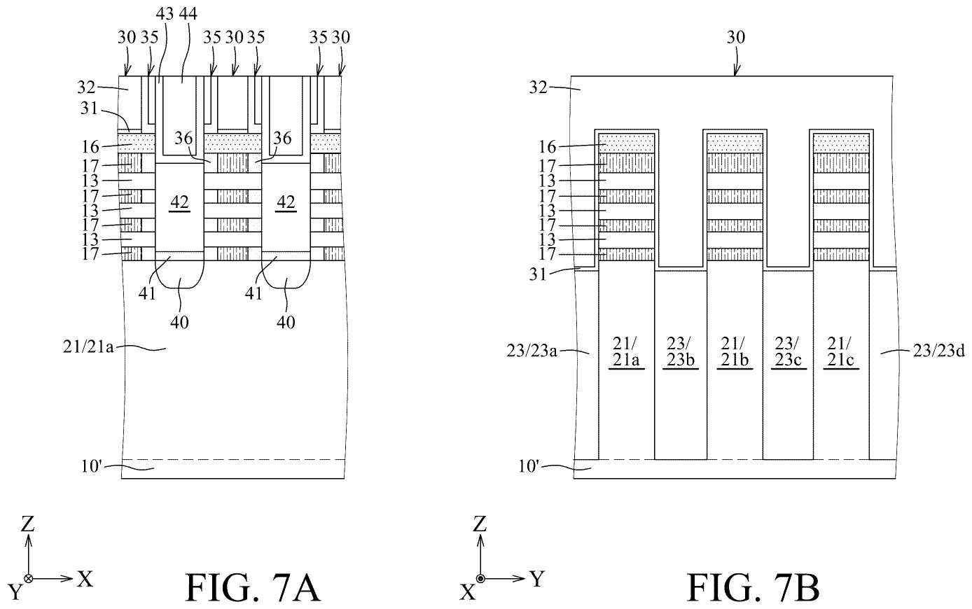

Referring to FIGS. 7A and 7B, each of the dielectric interposers 17 are trimmed by a selective etching process to have a reduced width in the X direction, while the channel portions 13 are substantially intact. Then, pairs of inner spacers 36 are formed by suitable deposition and etching techniques. Each pair of the inner spacers 36 are respectively formed at two opposite sides of a respective one of the dielectric interposers 17 in the X direction. In some embodiments, the inner spacers 36 may include silicon oxide, silicon oxycarbide, silicon oxynitride, silicon oxycarbide, silicon oxycarbonitride, air gap, other suitable low-k dielectric materials, or combinations thereof.

In some embodiments not shown herein, after forming the inner spacers 36, the channel portions 13 may be trimmed by a selective etching process to have a reduced width in the X direction.

Next, sill referring to FIGS. 7A and 7B, epitaxial portions 40, bottom isolations 41, and source/drain portions 42 are sequentially formed in the source/drain recesses 24 (see FIGS. 6A and 6B), such that each of the channel portions 13 extends between two corresponding adjacent ones of the source/drain portions 42.

In some embodiments, each of the epitaxial portions 40 includes a semiconductor material (such as the examples of the semiconductor material for forming the substrate 10). In some embodiments, each of the epitaxial portions 40 is independently made of non-doped silicon, silicon germanium, or boron-doped silicon. In some embodiments, each of the epitaxial portions 40 is formed by an epitaxial growth process (such as molecular-beam epitaxy (MBE), selective area epitaxy (SAE), etc.), or other suitable deposition techniques.

The bottom isolations 41 are respectively formed on the epitaxial portions 40 for electrical isolation. In some embodiments, each of the bottom isolations 41 includes or is made of silicon, silicon oxide, silicon nitride, carbon-doped silicon oxide, silicon oxycarbide, silicon oxynitride, silicon oxycarbon nitride, silicon carbon nitride, or combinations thereof. In some embodiments, formation of the bottom isolations 41 may include CVD, ALD, PVD, or other suitable deposition techniques, followed by an etching process to expose the channel portions 13.

In some embodiments, each of the source/drain portions 42 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 42 may each be doped with an n-type dopant so as to function as a source or a drain of an n-MOSFET, or may be doped with a p-type dopant so as to function as a source or a drain of a p-MOSFET. The n-type dopant may be, for example, but not limited to, phosphorous (P, ³¹P), arsenic (As), antimony (Sb), other suitable materials, or combinations thereof. The p-type dopant may be, for example, but not limited to, boron or boron compound (for example, B, ¹¹B, BF₂), aluminum (Al), gallium (Ga), indium (In), other suitable p-type dopants, or combinations thereof. In some other embodiments, the source/drain portions 42 serving as sources or drains of n-MOSFETs may include or be made of silicon phosphide (SiP), silicon arsenide (SiAs), or a combination thereof, and the source/drain portions 42 serving as sources or drains of p-MOSFETs may include or be made of silicon boron (SiB). In some embodiments, each of the source/drain portions 42 may be configured as a multi-layer structure including sub-layers which have different concentrations of dopants. In some embodiments, the source/drain portions 42 are formed by an epitaxial growth process (such as molecular-beam epitaxy (MBE), selective area epitaxy (SAE), etc.), or other suitable deposition techniques.

Then, a contact etch stop layer (CESL) 43 and an inter-layer dielectric (ILD) layer 44 are sequentially formed on the source/drain portions 42 by CVD, PVD, ALD, or other possible deposition processes, followed by a planarization process (e.g., CMP) to expose the dummy gate 32 of each of the dummy structures 30.

In some embodiments, the CESL 43 includes or is made of a dielectric material that is different from a dielectric material of the ILD layer 44, so that the CESL 43 may serve as an etch stop point during formation of metal contacts (e.g., the elements 71 shown in FIG. 11A). In certain embodiments, possible dielectric materials suitable for the CESL 43 include silicon nitride, silicon oxynitride, silicon carbonnitride, other suitable dielectric materials, or combinations thereof. In some embodiments, the ILD layer 44 includes or is made of silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof.

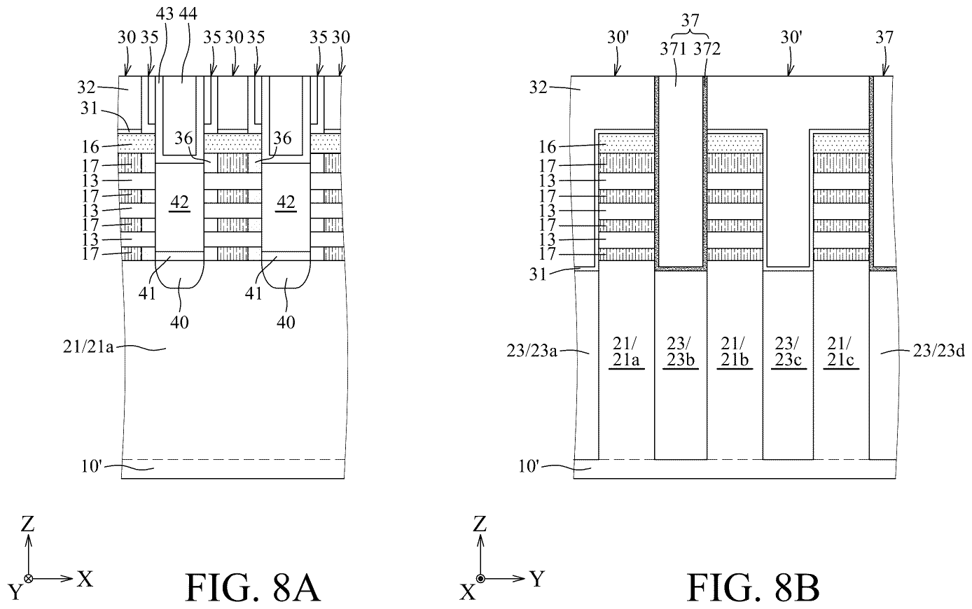

Referring to FIGS. 8A and 8B, dielectric walls 37 are formed, such that at least one of the dummy structures 30 (see FIG. 7B) is divided into dummy segments 30′. Each of the dielectric walls 37 is formed on a corresponding one of the isolation structures 23 and between two corresponding adjacent ones of the channel stacks. In some embodiments, each of the dielectric walls 37 is in contact with the channel portions 13 in the two corresponding adjacent ones of the channel stacks in the Y direction. In some embodiments, the dielectric walls 37 may extend lengthwise along the X direction, so that each of the dielectric walls 37 may extend into the ILD layer 44. The length of each of the dielectric walls 37 in the X direction may vary according to practical applications. In some embodiments, each of the dielectric walls 37 includes or is made of silicon nitride, silicon oxide, silicon oxynitride, silicon oxycarbide, silicon oxycarbon nitride, silicon carbon nitride, other suitable dielectric materials, or combinations thereof. In some embodiments, each of the dielectric walls 37 may be configured as a single layer structure or a multi-layered structure. For example, as shown in FIG. 8B, each of the dielectric walls 37 is formed as a bi-layered structure including a main wall portion 371 and a liner 372 which is disposed to separate the main wall portion 371 from two corresponding adjacent ones of the fin structures 20. The main wall portion 371 and the liner 372 are made of different materials. In some embodiments, the dielectric material of the liner 372 may be the same as or similar to the dielectric material of the dielectric interposers 17.

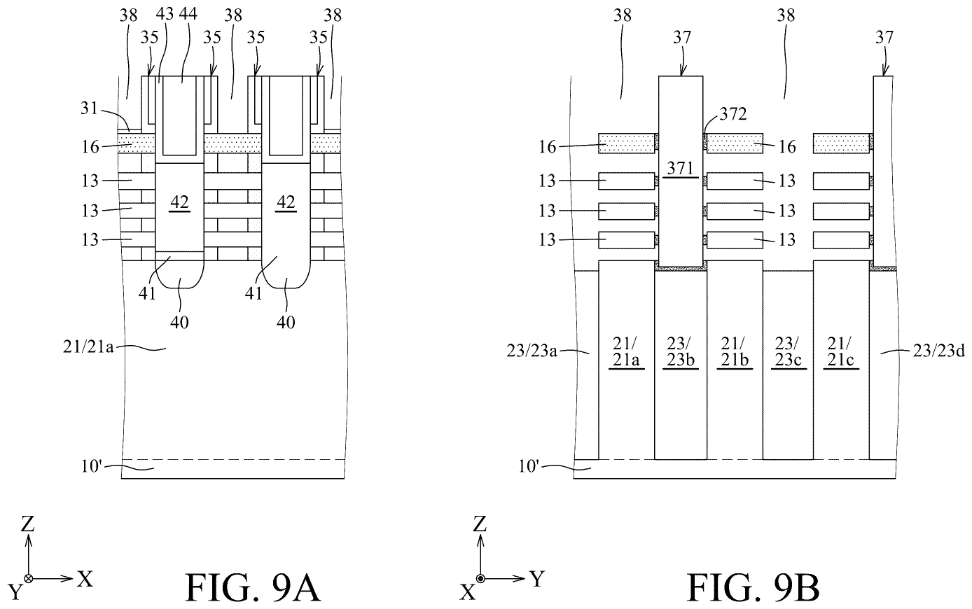

Referring to FIGS. 9A and 9B, the dummy segments 30′, the remaining dummy structures 30 and the dielectric interposers 17 (see FIGS. 8A and 8B) are removed, and then the liner 372 of each of the dielectric walls 37 is partially removed to expose the main wall portion 372, thereby forming cavities 38. For each of the dielectric walls 37, remaining portions of the liner 372 are each located between the main wall portion 371, and a corresponding adjacent one of the channel portions 13 and the protection portion 16. Furthermore, each of the remaining portions of the liner 372 is recessed inwardly without being completely removed. Therefore, as shown in FIG. 9B, each of the cavities 38 may extend to be located between the main wall portion 371 of one of the dielectric walls 37, and a corresponding adjacent one of the channel portions 13 and the protection portion 16. In some embodiments, the cavities 38 are formed by an etching process (for example, but not limited to, dry etching, wet etching, or a combination thereof).

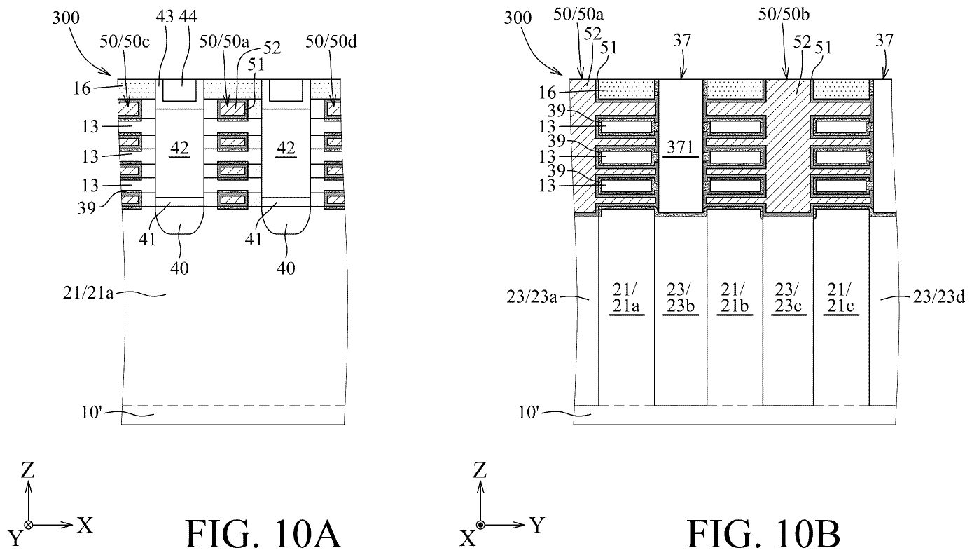

Referring to FIGS. 10A and 10B, interfacial layers 39 are respectively formed on the channel portions 13. The interfacial layers 39 serve to provide a good adhesion between the channel portions 13 and a gate dielectric layer to be subsequently formed on the channel portions 13. In some embodiments, the interfacial layers 39 are made of silicon oxide, and are formed by an oxidation reaction that happens on a surface region of each of the channel portions 13.

Next, still referring to FIGS. 10A and 10B, gate structures 50 (including the gate structures 50a, 50b, 50c, 50d) are respectively formed to fill the cavities 38, such that each of the gate structures 50 is disposed around the channel portions 13 and the protective portion 16 of a corresponding one of the channel stacks. Each of the gate structures 50 includes a gate electrode 52, and a gate dielectric layer 51 disposed to separate the gate electrode 52 from the channel portions 13 and the protection portion 16 of the corresponding one of the channel stacks. In some embodiments, each of the gate structures 50 extends lengthwise along the Y direction.

As shown in FIG. 10B, the gate dielectric layer 51 includes a first dielectric portion disposed beneath the protection portion 16, and a second dielectric portion disposed around the channel portions 13.

The gate electrode 52 includes inner gate portions and an outer gate portion. Each of the inner gate portions is sandwiched between two adjacent ones of the channel portions 13 and the protection portion 16, or between a bottommost one of the channel portions 13 and a corresponding one of the protrusions 21. The outer gate portion is disposed to connect each of the inner gate portions, and covers the channel portions 13 and the protection portion 16. In some embodiments, the outer gate portion is located on a corresponding one of the isolation structures 23.

In some embodiments, the gate dielectric layer 51 includes a metal-containing high-k dielectric layer (having a k-value not less than about 9 or larger than about 30), such as metal oxides of hafnium, tantalum, titanium, zirconium, aluminum, lanthanum, yttrium, other suitable metals, or combinations thereof. The k-value of the gate dielectric layer 51 is greater than the k-value of the gate spacers 35. The k-value of the gate dielectric layer 51 is at least twice the k-value of the ILD layer 44. In some embodiments, the gate dielectric layer 51 may have a thickness ranging from about 1 nm to about 10 nm. The gate electrode 52 may include at least one metal layer. In some embodiments, the gate electrode 52 includes at least one work function layer which is provided for adjusting threshold voltage of n-MOSFETs or p-MOSFETs in the device structure 300. In some embodiments, the gate electrode 52 includes a titanium-based material, such as TiN, TiAlC, or other suitable suitable materials.

In some embodiments, the gate structures 50 may be formed by multiple deposition processes (such as CVD, ALD, PVD, or other suitable deposition processes), multiple photolithography processes, multiple etching processes, multiple thermal processes, and multiple planarization processes (e.g., CMP), or other suitable processes, so that the gate structures 50 may include different materials for adjusting threshold voltage. It is noted that the final height of the gate structures 50 in the Z direction may be adjusted by a planarization process using the protection portion 16 as a stop layer. For example, as shown in FIGS. 10A and 10B, an uppermost surface 50s of each of the gate structures 50 (i.e., an upper surface of the outer gate portion of the gate electrode 52 of each of the gate structures 50) is substantially flush with an upper surface of the protection portion 16 of each of the channel stacks. In such case, the upper surface of the protection portion 16 is prevented from being covered by the gate dielectric layer 51, but a lower surface of the protection portion 16 is still covered by the gate dielectric layer 51. It is noted that the uppermost surface 50s of each of the gate structures 50 and the upper surface of the protection portion 16 of each of the channel stacks may be planar, as shown in FIG. 10B. In some other embodiments, the uppermost surface 50s of each of the gate structures 50 and the upper surface of the protection portion 16 of each of the channel stacks may be non-planar.

After forming the gate structures 50, the device structure 300 is thus obtained.

Referring to FIGS. 11A and 11B, metal contacts 71 and via contacts 72 (one of which is exemplarily shown in, for example, FIG. 11A) are formed. Each of the via contacts 72 is connected to one of the source/drain portions 42 through a corresponding one of the metal contacts 71. The structure shown in FIGS. 11A and 11B is obtained after step S02 of the method 100 as shown in FIG. 1.

Firstly, dielectric layers 61, 62 are sequentially formed on the device structure 300 by CVD, ALD, PVD, or other suitable deposition techniques. The dielectric layers 61, 62 are made of different materials. In some embodiments, the k-value of the dielectric layer 62 is lower than the k-value of the dielectric layer 61. Possible dielectric materials suitable for forming the dielectric layer 61 and the dielectric layer 62 are respectively the same as or similar to those for the CESL 43 and the ILD layer 44, and thus the details thereof are omitted for the sake of brevity. Next, the metal contacts 71 are formed. Each of the metal contacts 71 penetrates through the dielectric layers 62, 61, the ILD layer 44 and the CESL 43 so as to connect to a corresponding one of the source/drain portions 42. In some embodiments, the metal contacts 71 may include a conductive material, such as tungsten (W), aluminum (Al), ruthenium (Ru), cobalt (Co), copper (Cu), palladium (Pd), nickel (Ni), platinum (Pt), a low resistivity metal constituent, etc., or combinations thereof. In some embodiments, metal silicide layers 70 are each formed between one of the metal contacts 71 and a corresponding one of the source/drain portions 42, so as to reduce a contact resistance (Rcsd) between the one of the metal contacts 71 and the corresponding one of the source/drain portions 42. In some embodiments, the metal silicide layers 70 may be made of a metal silicide including titanium (Ti), nickel (Ni), cobalt (Co), ruthenium (Ru), molybdenum (Mo), or combinations thereof. The material(s) of the metal silicide layers 70 may vary according to the material(s) of the source/drain portions 42 to be connected. Then, dielectric layers 63, 64 are sequentially formed on the dielectric layer 62 by CVD, ALD, PVD, or other suitable deposition techniques. The dielectric layers 63, 64 are made of different materials. In some embodiments, the k-value of the dielectric layer 64 is lower than the k-value of the dielectric layer 63. In some embodiments, the k-value of the dielectric layer 63 is greater than the k-value of the dielectric layer 62. Possible dielectric materials suitable for forming the dielectric layer 63 and the dielectric layer 64 are respectively the same as or similar to those for the CESL 43 and the ILD layer 44, and thus the details thereof are omitted for the sake of brevity. Afterwards, the via contacts 72 are formed to penetrate through the dielectric layers 64, 63, such that each of the via contacts 72 is connected to a corresponding one of the metal contacts 71. Possible conductive materials suitable for the via contacts 72 are similar to those for the metal contacts 71, and thus the details thereof are omitted for the sake of brevity.

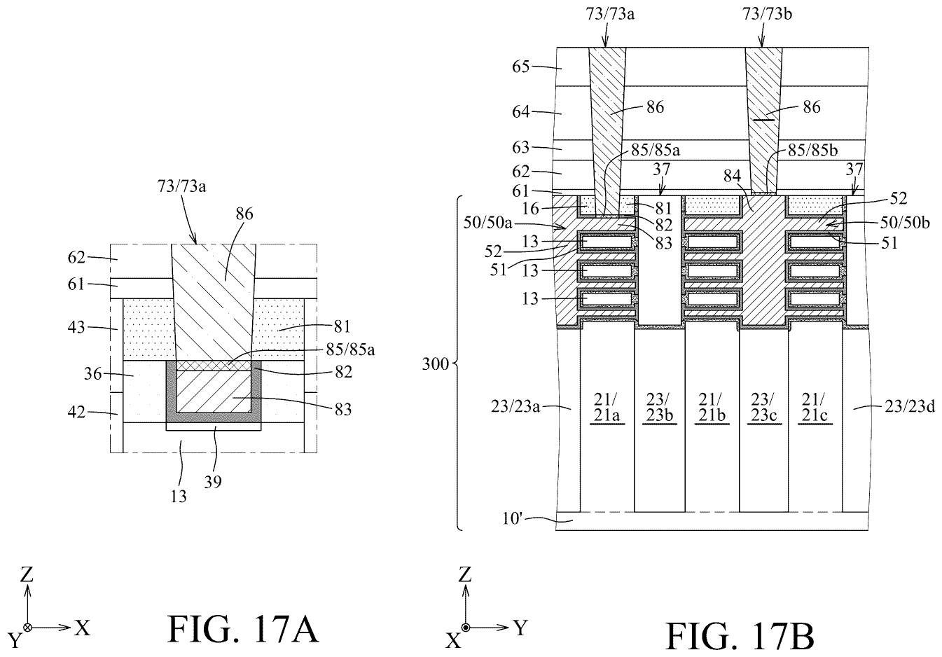

The following paragraphs describe processes of forming the gate contacts 73 (including the gate contacts 73a, 73b), each of which is connected to the gate electrode 52 of a corresponding one of the gate structures 50. In some embodiments, the gate contacts 73a, 73b may be formed at different locations. For example, as shown in FIG. 17B, the gate contact 73a is located above the protrusion 21a. The gate contact 73a extends downwardly though the protection portion 16 of a corresponding one of the channel stacks on the protrusion 21a, and the first dielectric portion of the gate dielectric layer 51 of the gate structure 50a, so that the gate contact 73a is connected to an uppermost one of the inner gate portions of the gate electrode 52 of the gate structure 50a. The gate contact 73b is located above the isolation structure 23c, and is connected to the outer gate portion of the gate electrode 52 of the gate structure 50b. In such case, the gate contact 73a has a depth in the Z direction that is greater than a depth of the gate contact 73b in the Z direction.

For the sake of brevity, the protection portion 16 of the corresponding one of the channel stacks on the protrusion 21a is referred to as a gate protection feature 81. The first dielectric portion of the gate dielectric layer 51 of the gate structure 50a, which is located beneath the gate protection feature 81, is referred to as a high-k dielectric feature 82. The k-value of the high-k dielectric feature 82 is greater than the k-value of the gate protection feature 81. The uppermost one of the inner gate portions of the gate electrode 52 of the gate structure 50a is referred to as an inner gate feature 83 of the gate structure 50a. The outer gate portion of the gate electrode 52 of the gate structure 50b is referred to as an outer gate feature 84 of the gate structure 50b. Formation of the gate contacts 73a, 73b may include steps S03 to S07 of the method 100 shown in FIG. 1.

Referring to FIGS. 12A and 12B, via openings 74 (including the via openings 74a, 74b) are formed. The via openings 74a, 74b are respectively configured to form the gate contacts 73a, 74b therein. The structure shown in FIGS. 12A and 12B is obtained after step S03 of the method 100 as shown in FIG. 1.

Firstly, a dielectric layer 65 is formed on the dielectric layer 64 by CVD, ALD, PVD, or other suitable deposition techniques. Possible dielectric materials suitable for forming the dielectric layer 65 are the same as or similar to those for the ILD layer 44, and thus the details thereof are omitted for the sake of brevity.

Next, a patterned mask layer (not shown) is formed on the dielectric layer 65 by a photolithography process. The patterned mask layer may be configured as a single photoresist layer, a bi-layered structure or a tri-layered structure.

Then, an anisotropic etching process is performed to form the via openings 74a, 74b using the patterned mask layer as an etch mask. The via opening 74a extends downwardly from an upper surface of the dielectric layer 65 to penetrate through the dielectric layers 65, 64, 63, 62, 61 and the gate protection feature 81 located above the protrusion 21a until a portion of the high-k dielectric feature 82 is exposed through the via opening 74a. The via opening 74b extends downwardly from the upper surface of the dielectric layer 65 to penetrate through the dielectric layers 65, 64, 63, 62, 61, until a portion of the outer gate feature 84 of the gate structure 50b is exposed through the via opening 74b. The via opening 74b is located above the isolation structure 23c.

In some embodiments, the anisotropic etching process includes a dry etching process, a plasma etching process (such as an inductively coupled plasma reactive ion etch, reactive ion beam etching, etc.), or the like. In some embodiments, a halogen-containing precursor gas (such as a fluorine-containing gas, a chlorine-containing gas, a bromine-containing gas, or combinations thereof), CH₄, N₂, O₂, H₂, or combinations thereof, are used to generate a plasma used in the anisotropic etching process to form the via openings 74a, 74b. The halogen-containing precursor gas may include HBr, Cl₂, CF₄, CHF₃, CH₃F, CH₂F₂, C₄F₈, C₄F₆, SF₆, other suitable halogen-containing gases, or combinations thereof. After the anisotropic etching process, the patterned mask layer is removed by, for example, but not limited to, an ashing process, a photoresist stripping process, an etching process, or combinations thereof.

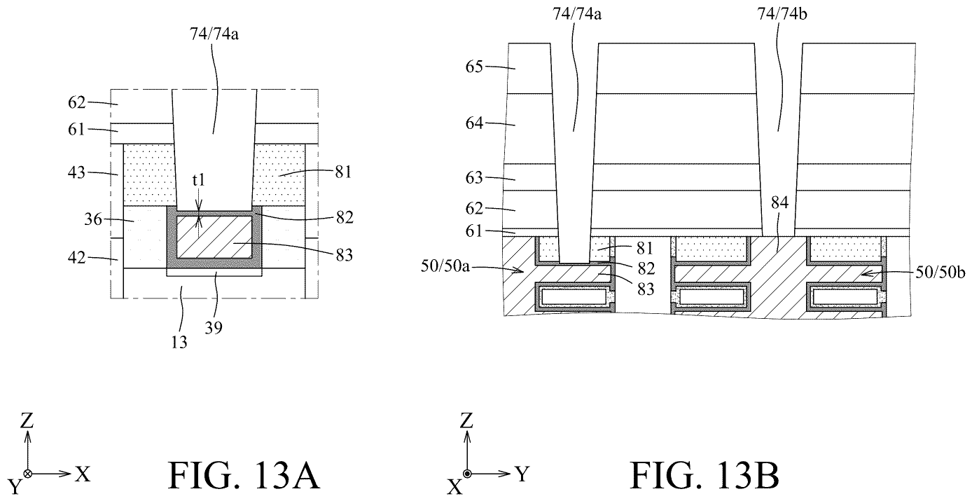

Referring to FIGS. 13A and 13B, a wet etching process is performed on structure shown in FIGS. 12A and 12B, so that the portion of the high-k dielectric feature 82 has a reduced thickness t1 (for example, but not limited to, ranging from about 0.5 nm to about 3 nm), while the portion of the outer gate feature 84 of the gate structure 50b is substantially intact. FIG. 13A is an enlarged fragmentary view of area C shown in FIG. 12A, but illustrating an intermediate structure obtained after step S04 of the method 100 as shown in FIG. 1 in accordance with some embodiments. FIG. 13B is a sectional view similar to that of FIG. 12B, but, for the sake of brevity, an upper portion of the intermediate structure obtained after step S04 is shown in FIG. 13B, while a lower portion of the intermediate structure is not shown in FIG. 13B.

In some embodiments, wet etchants used in step S04 may include NH₄OH, H₂SO₄, H₂O₂, HCl, H₂O, HF, HNO₃, diluted HF, O₃, H₃PO₄, other suitable etchants, or combinations thereof.

Since the inner gate feature 83 of the gate structure 50a is protected by the high-k dielectric feature 82, the inner gate feature 83 may be prevented from oxidation before performing step S05.

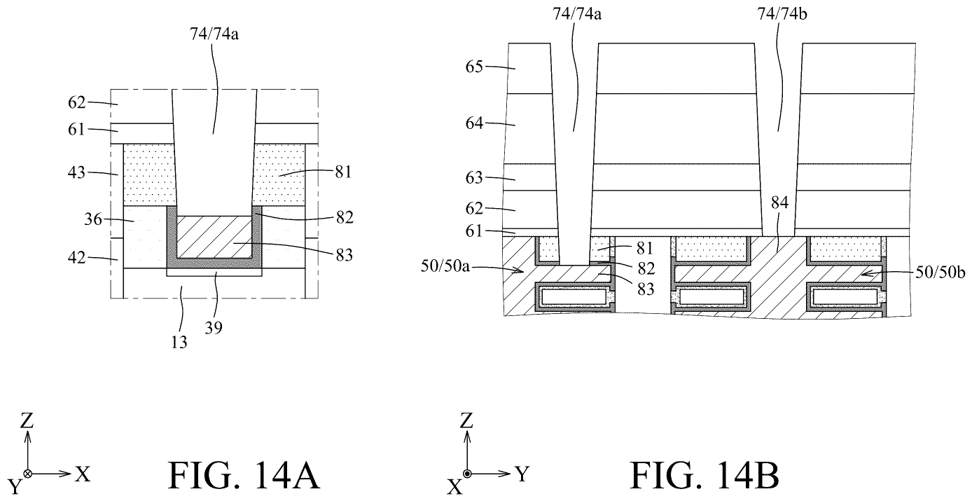

Referring to FIGS. 14A and 14B, a non-plasma etching process is performed on the structure shown in FIGS. 13A and 13B, so that the portion of the high-k dielectric feature 82 and the portion of the outer gate feature 84 of the gate structure 50b are subjected to the non-plasma etching process through the via opening 74a and the via opening 74b, respectively. After the non-plasma etching process, the via opening 74a penetrates through the high-k dielectric feature 82 to expose a portion of the inner gate feature 83 of the gate structure 50a, while the portion of the outer gate feature 84 of the gate structure 50b is substantially intact. The structure shown in FIGS. 14A and 14B is obtained after step S05 of the method 100 as shown in FIG. 1.

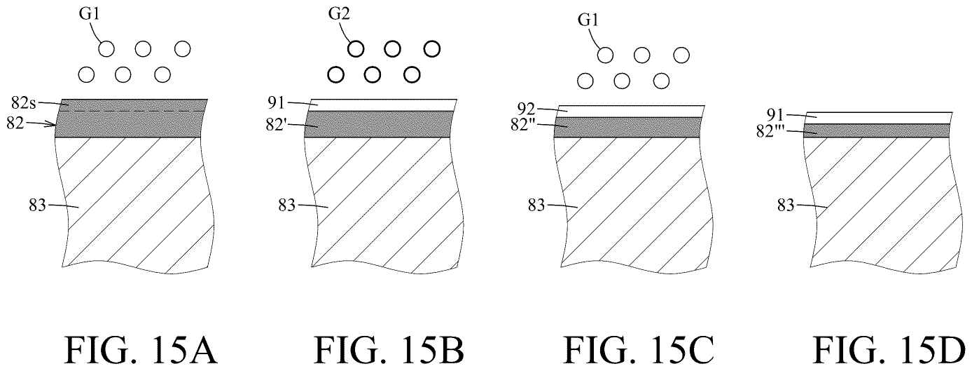

FIGS. 15A to 15D illustrate enlarged fragmentary sectional views of the intermediate structures of the portion of the high-k dielectric feature 82 at different intermediate stages of the non-plasma etching process (step S05) in accordance with some embodiments. In some embodiments, the non-plasma etching process is a gas soaking process which is conducted in a first process chamber at a pressure ranging from about 0.1 torr to about 10 torr and at a temperature ranging from about 150 to about 400° C.

Referring to FIG. 15A, a surface region 82s of the high-k dielectric feature 82 is reacted with a first halogen-containing gas G1. In some embodiments, the first halogen-containing gas G1 is introduced into the first process chamber with a flow rate ranging from about 10 sccm to about 250 sccm. As the first halogen-containing gas G1 is adsorbed onto an exposed surface of the high-k dielectric feature 82, the surface region 82s of the high-k dielectric feature 82 reacts with the first halogen-containing gas G1 to form a first film 91 (see FIG. 15B) on a remaining high-k dielectric feature 82′.

The first halogen-containing gas G1 contains a first halogen, such as F, Cl, Br, or I. In some embodiments, the first halogen-containing gas G1 includes hydrogen halide, nitrogen halide, ammonium halide, metal halide (such as tungsten halide or other suitable metal halides), carbon fluoride, alkyl halide, sulfur halide, or other suitable halogen-containing gases, or combinations thereof, and the surface region 82s of the high-k dielectric feature 82 is halogenated by the first halogen-containing gas G1. In certain embodiments, the first halogen-containing gas G1 includes HF, NF₃, NH₄F, WF₆, CF₄, CHF₃, CH₃F, CH₂F₂, C₄F₈, C₄F₆, SF₆, or combinations thereof. In some embodiments, the first film 91 includes metal halide such as hafnium fluoride, metal oxide such as tungsten oxide, metal oxyhalide such as tungsten oxyhalide, or combinations thereof, but is not limited thereto. The material composition of the first film 91 depends on the high-k dielectric feature 82 and the first halogen-containing gas G1. Some gaseous byproducts (for example, but not limited to, H₂O, H₂, nitrogen oxides, carbon dioxide, sulfur dioxide, or combinations thereof) may be formed during halogenation of the surface region 82s of the dielectric feature 82, and may be purged from the first process chamber along with a remainder of the first halogen-containing gas G1 before a subsequent atomic layer clean treatment is performed. The material composition of the gaseous byproducts produced during the halogenation of the surface region 82s of the dielectric feature 82 depends on the high-k dielectric feature 82 and the first halogen-containing gas G1.

Next, an atomic layer clean treatment is repeatedly performed. The atomic layer clean treatment may be also referred to as an atomic layer etch treatment or an etch cycle, and includes a first gas soaking step and a second soaking step which are separately performed.

Referring to FIG. 15B, in the first gas soaking step, a second halogen-containing gas G2 is introduced into the first process chamber with a flow rate ranging from about 10 sccm to about 250 sccm. The first film 91 reacts with the second halogen-containing gas G2, such that the first film 91 is removed to expose the remaining high-k dielectric feature 82′. Immediately afterwards, a surface region of the remaining high-k dielectric feature 82′ reacts with the second halogen-containing gas G2 to form a second film 92 (see FIG. 15C) on a remaining high-k dielectric feature 82″ (if any).

The second halogen-containing gas G2 is selected from a gas that is capable of removing the first film 91 after reacting with the second halogen-containing gas G2. To be specific, the second halogen-containing gas G2 contains a second halogen (such as F, Cl, Br, or I) that is different from the first halogen, so as to facilitate the reaction between the second halogen-containing gas G2 and the first film 91. In such case, the second film 92 thus formed may be different from the first film 91. In some embodiments, the second halogen-containing gas G2 includes non-metal halide (such as boron halide), metal halide (such as molybdenum halide, tungsten halide, titanium halide, or other suitable metal halides), or other suitable halogen-containing gases, or combinations thereof. It is noted that when each of the first halogen-containing gas G1 and the second halogen-containing gas G2 includes metal halide, the metal in the second halogen-containing gas G2 may be different from the metal in the first halogen-containing gas G1, so as to facilitate the reaction between the second halogen-containing gas G2 and the first film 91. In certain embodiments, the second halogen-containing gas G2 includes boron chloride (for example, BCl₃), molybdenum chloride (MoCl₅), tungsten chloride (for example, WCl₆, WCl₅), titanium chloride (TiCl₄), or combinations thereof. In some embodiments, the second film 92 includes oxides (such as boron oxide, molybdenum oxide, tungsten oxide, titanium oxide, or combinations thereof), but is not limited thereto. The material composition of the second film 92 depends on the remaining high-k dielectric feature 82′, the second halogen-containing gas G2, and the first film 91 to be removed. Some gaseous byproducts (for example, but not limited to, hafnium chloride, boron fluoride, tungsten chloride, or combinations thereof) may be formed during the removal of the first film 91 and formation of the second film 92, and may be purged from the first process chamber along with a remainder of the second halogen-containing gas G2 before the second gas soaking step is performed. The material composition of the gaseous byproducts formed during the removal of the first film 91 and formation of the second film 92 depends on the remaining high-k dielectric feature 82′, the second halogen-containing gas G2, and the first film 91 to be removed.

Referring to FIG. 15C, in the second gas soaking step, the first halogen-containing gas G1 is introduced into the first process chamber with a flow rate ranging from about 10 sccm to about 250 sccm. The second film 92 reacts with the first halogen-containing gas G1, such that the second film 92 is removed to expose the remaining high-k dielectric feature 82″ (if any). Immediately afterwards, a surface region of the remaining high-k dielectric feature 82″ (if any) reacts with the first halogen-containing gas G1 to form a third film 91 (see FIG. 15D) on a remaining high-k dielectric feature 82″′ (if any).

The first halogen-containing gas G1 (such as the examples of the first halogen-containing gas G1 as described above) is selected from a gas that is capable of removing the second film 92 after reacting with the first halogen-containing gas G1. The material composition of the third film 91 depends on the remaining high-k dielectric feature 82″, the first halogen-containing gas G1, and the second film 92 to be removed. Since the material composition of the third film may be the same as or similar to that of the first film, the third film is also denoted by the reference numeral 91. Some gaseous byproducts (for example, but not limited to, H₂O, H₂, nitrogen oxides, carbon dioxide, sulfur dioxide, boron fluoride, or combinations thereof) may be formed during the removal of the second film 92 and formation of the third film 91, and may be purged from the first process chamber along with a remainder of the first halogen-containing gas G1 before the first gas soaking step of the next etch cycle is performed. The material composition of the gaseous byproducts formed during the removal of the second film 92 and formation of the third film 91 depends on the remaining high-k dielectric feature 82″, the first halogen-containing gas G1, and the second film 92 to be removed.

In some alternative embodiments, the first halogen-containing gas G1 includes non-metal halide (such as boron halide), metal halide (such as molybdenum halide, tungsten halide, titanium halide, or other suitable metal halides), or other suitable halogen-containing gases, or combinations thereof. For example, the second halogen-containing gas G2 includes boron chloride, molybdenum chloride, tungsten chloride, titanium chloride, or combinations thereof. Furthermore, the second halogen-containing gas G2 may include hydrogen halide, ammonium halide, nitrogen halide, metal halide (such as tungsten halide), or other suitable halogen-containing gases, or combinations thereof. For example, the first halogen-containing gas G1 includes HF, NF₃, NH₄F, WF₆, CF₄, CHF₃, CH₃F, CH₂F₂, C₄F₈, C₄F₆, SF₆, or combinations thereof. In such case, the first film 91 thus formed includes oxides (such as boron oxide, molybdenum oxide, tungsten oxide, titanium oxide, or combinations thereof), halides, or combinations thereof, and the second film 92 thus formed includes metal halide.

It is noted that formation of the first film 91 and the second film 92 is based on a self-limiting surface reaction. That is, the reaction to form the film 91 or 92 will stop when open active sites located on the exposed surface of the high-k dielectric feature 82, 82′, 82″, 82″′ are no longer available for the halogen-containing gas G1 or G2 to react, thereby allowing a precise control of the thickness of the film 91 or 92.

During the non-plasma etching process, the thicknesses of the high-k dielectric feature 82 gradually decrease as the first gas soaking step and the second gas soaking step are repeatedly and alternately performed. The non-plasma etching process is completed when remaining high-k dielectric feature is no longer available to react with the first halogen-containing gas G1 or the second halogen-containing gas G2 through the via opening 74a. That is, the non-plasma etching process is completed once the portion of the inner gate feature 83 is exposed through the via opening 74a. In some embodiments, when the high-k dielectric feature 82 is completely removed, byproducts formed during removal of the first film 91 or removal of the second film 92 may be left on the portion of the inner gate feature 83. In such case, the byproducts may be removed by an additional non-plasma process (for example, but not limited to, a thermal treatment, an additional gas soaking process using suitable etchants, or a combination thereof) so as to expose the portion of the inner gate feature 83.

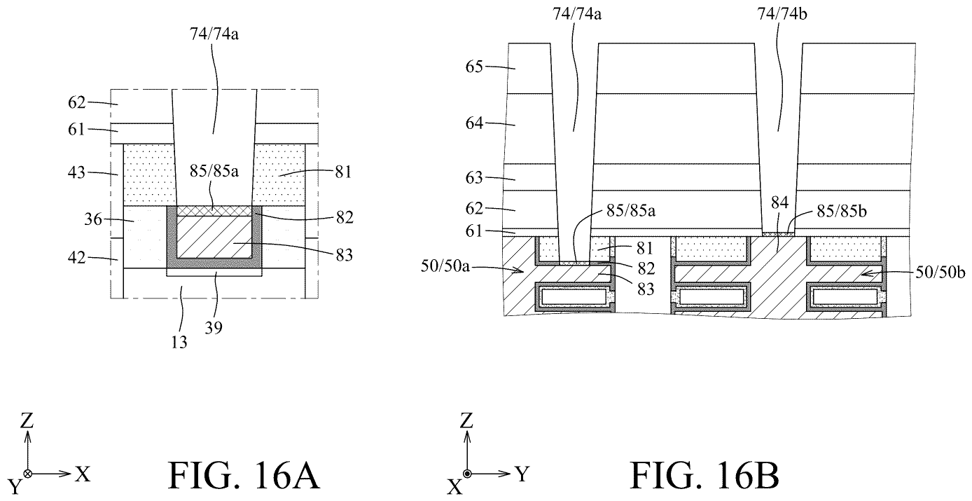

Referring to FIGS. 16A and 16B, conductive cap portions 85 (including the conductive cap portions 85a, 85b) are respectively formed on the portion of the inner gate feature 83 and the portion of the outer gate feature 84, so that the portion of the inner gate feature 83 and the portion of the outer gate feature 84 may be prevented from being exposed through the via opening 74a and the via opening 74b, respectively. The structure shown in FIGS. 16A and 16B is obtained after step S06 of the method 100 as shown in FIG. 1.

In some embodiments, the conductive cap portions 85 include W, Ti, Mo, Ru, Ir, Re, Rh, Nb, other suitable conductive materials, or combinations thereof. In some embodiments, the conductive cap portions 85 are formed by a non-plasma deposition process, such as thermal CVD, thermal ALD, or other suitable deposition techniques. In some embodiments, a metal-containing precursor gas (such as WF₆, WCl₅, WCl₆, trimethylaluminum, MoCl₅, RuF₃, RuCl₃, or other suitable metal-containing precursor gas) and a reducing gas (such as H₂) are used to form the conductive cap portion 85. In some embodiments, each of the conductive cap portions 85 has a thickness (measured in the Z direction) less than a thickness of the dielectric layer 61. In some embodiments, the thickness of each of the conductive cap portions 85 may range from about 1 nm to about 15 nm. In some embodiments, each of the conductive cap portions 85 independently has a dimension (measured in the X direction) ranging from about 1 nm to about 29 nm. The dimension of the conductive cap portions 85a may be the same as or different from (e.g., smaller than) the dimension of the conductive cap portions 85b.

In some embodiments, step S05 and step S06 are respectively conducted in the first process chamber and a second process chamber which are different process chambers in a same apparatus. It is worth noting that the non-plasma etching process (step S05) and formation of the conductive cap portion 85 (step S06) are continuously performed without breaking vacuum. As such, the deposition process for forming the conductive cap portion 85 may be also referred to as an in-situ deposition process. To be specific, the structure obtained after step S05 is transferred from the first process chamber to the second process chamber under a pressure not greater than about 0.1 torr (for example, but not limited to, ranging from about 10⁻⁷ torr to about about 0.1 torr). Hence, surface oxidation of the portion of the inner gate feature 83 and the portion of the outer gate feature 84 due to vacuum break during transfer from the first process chamber the second process chamber may be prevented, thereby reducing the contact resistance between each of the gate contacts 73 and a corresponding gate electrode 52 (see FIGS. 17A and 17B). In addition, threshold voltage shift of an n-MOSFET or a p-MOSFET in the device structure 300 due to material loss of the inner gate feature 83 may also be prevented.

Referring to FIGS. 17A and 17B, conductive filling portions 86 are formed to respectively fill the via openings 74a, 74b (see FIG. 16B), thereby obtaining gate contacts 73a, 73b. Each of the gate contacts 73a, 73b includes one of the conductive cap portions 85 and a corresponding one of the conductive filling portions 86. The semiconductor structure 200 is thus formed. The structure shown in FIGS. 17A and 17B is obtained after step S07 of the method 100 as shown in FIG. 1.

In some embodiments, the conductive filling portions 86 include W, Ti, Mo, Ru, Ir, Re, Rh, Nb, other suitable conductive materials, or combinations thereof. The conductive material of the conductive filling portions 86 may be the same as or different from the conductive material of the conductive cap portions 85. In some embodiments, the conductive filling portions 86 may be formed by PVD, CVD, ALD, or other suitable deposition techniques. In some embodiments, the conductive filling portions 86 may be formed immediately after the conductive cap portions 85 without changing the process chamber. That is, the conductive filling portions 86 and the conductive cap portions 85 may be formed in the same process chamber. In some embodiments, each of the conductive filling portions 86 independently has a bottom dimension (measured in the X direction) ranging from about 1 nm to about 30 nm. The bottom dimension of the conductive filling portions 86a may be the same as or different from (e.g., smaller than) the bottom dimension of the conductive filling portions 86b.

Referring to FIGS. 18A and 18B, the semiconductor structure 200 may be further formed with a back-end-of-line (BEOL) interconnect structure thereon, so as to permit an operating voltage to be applied to each of the source/drain portions 42 and to be applied to the gate electrode 52 of each of the gate structures 50 through the BEOL interconnect structure. The structure shown in FIGS. 18A and 18B is obtained after step S08 of the method 100 as shown in FIG. 1.

Before forming the BEOL interconnect structure, a planarization process (e.g., CMP) may be performed on the structure shown in FIGS. 17A and 17B until the via contacts 72 are exposed. In some embodiments, each of the conductive filling portions 86 independently has a top dimension (measured in the X direction) ranging from about 2 nm to about 40 nm. The top dimension of the conductive filling portions 86a may be the same as or different from (e.g., smaller than) the top dimension of the conductive filling portions 86b.

In some embodiments, the BEOL interconnect structure may include an inter-metal dielectric (IMD) portion 66 in which a plurality of electrically conductive elements (for example, metal contacts, metal lines and/or metal vias) are formed so as to permit each of the source/drain portions 42 and the gate electrode 52 of each of the gate structures 50 to be electrically connected to a power supply through the electrically conductive elements. For example, metal lines 75 are exemplarily shown in FIG. 18A. Each of the metal lines 75 is formed over a corresponding one of the via contacts 72 and the gate contacts 73. The BEOL interconnect structure may be formed by a dual damascene process, a single damascene process, or other suitable back-end-of-line (BEOL) techniques.

In some alternative embodiments, the semiconductor structure 200 may further include additional features, and/or some features present in the semiconductor structure 200 may be modified, replaced, or eliminated without departure from the spirit and scope of the present disclosure.

In summary, the via opening 74a, by conducting the non-plasma etching process, penetrates through the high-k dielectric feature 82, and then the portion of the inner gate feature 83 exposed through the via opening 74a is protected by the conductive cap portion 85a using the in-situ deposition process without breaking vacuum. Therefore, the portion of the inner gate feature 83 may be prevented from oxidation. In addition, since the atomic layer clean treatment is included in the non-plasma etching process, the inner gate feature 83 may be prevented from damage or material loss due to over-etching. The gate contact 73a thus obtained may have a reduced contact resistance to the inner gate feature 83, thereby improving the device performance of the semiconductor structure 200.

In accordance with some embodiments of the present disclosure, a method for manufacturing a semiconductor structure includes: forming a base structure on a substrate, the base structure including a gate electrode and a gate dielectric layer covering the gate electrode; forming a via opening extending from an upper surface of the base structure to expose the gate dielectric layer; performing a non-plasma etching process on the gate dielectric layer through the via opening until the via opening penetrates the gate dielectric layer to expose a portion of the gate electrode; and forming a conductive cap portion on the portion of the gate electrode, so as to prevent the portion of the gate electrode from being exposed through the via opening. The non-plasma etching process and formation of the conductive cap portion are performed without breaking vacuum.

In accordance with some embodiments of the present disclosure, the non-plasma etching process includes at least one etch cycle, in which a first halogen-containing gas and a second halogen-containing gas are sequentially applied on the gate dielectric layer in such order, such that a surface region of the gate dielectric layer exposed to the via opening is removed after each cycle of the at least one etch cycle. A halogen element in the first halogen-containing gas is different from a halogen element in the second halogen-containing gas.

In accordance with some embodiments of the present disclosure, the non-plasma etching process includes a gas soaking process.

In accordance with some embodiments of the present disclosure, the first halogen-containing gas includes hydrogen halide, nitrogen halide, ammonium halide, metal halide, carbon fluoride, alkyl halide, sulfur halide, or combinations thereof, and the second halogen-containing gas includes non-metal halide, metal halide, or a combination thereof.

In accordance with some embodiments of the present disclosure, the first halogen-containing gas includes HF, NF₃, NH₄F, WF₆, CF₄, CHF₃, CH₃F, CH₂F₂, C₄F₈, C₄F₆, SF₆, or combinations thereof, and the second halogen-containing gas includes BCl₃, MoCl₅, WCl₅, TiCl₄, or combinations thereof.

In accordance with some embodiments of the present disclosure, the non-plasma etching process is performed at a pressure ranging from 0.1 torr to 10 torr.

In accordance with some embodiments of the present disclosure, the conductive cap portion is formed by thermal CVD or thermal ALD.

In accordance with some embodiments of the present disclosure, the conductive cap portion includes W, Ti, Mo, Ru, Ir, Re, Rh, Nb, or combinations thereof.

In accordance with some embodiments of the present disclosure, a method for manufacturing a semiconductor structure includes: forming a base structure on a substrate, the base structure including a gate electrode and a gate dielectric layer covering the gate electrode; forming a via opening extending from an upper surface of the base structure to expose a surface region of the gate dielectric layer; performing a non-plasma etching process on the surface region of the gate dielectric layer through the via opening until the via opening penetrates the gate dielectric layer to expose a portion of the gate electrode; forming a conductive cap portion on the portion of the gate electrode, so as to prevent the portion of the gate electrode from being exposed through the via opening. The non-plasma etching process and formation of the conductive cap portion are performed without breaking vacuum. The non-plasma etching process includes: subjecting the surface region of the gate dielectric layer to react with a first halogen-containing gas so as to form a first film, the first halogen-containing gas containing a first halogen; and performing an atomic layer clean treatment. The atomic layer clean treatment includes: subjecting the first film to react with a second halogen-containing gas, so as to remove the first film and to form a second film different from the first film, the second halogen-containing gas containing a second halogen different from the first halogen; subjecting the second film to react with the first halogen-containing gas, so as to remove the second film and to form the first film. The non-plasma etching process further includes: repeating the atomic layer clean treatment until the portion of the gate electrode is exposed through the via opening.

In accordance with some embodiments of the present disclosure, the first halogen-containing gas includes hydrogen halide, nitrogen halide, ammonium halide, metal halide, carbon fluoride, alkyl halide, sulfur halide, or combinations thereof, and the first film includes metal halide. The second halogen-containing gas includes non-metal halide, metal halide, or a combination thereof, and the second film includes oxides.

In accordance with some embodiments of the present disclosure, the first halogen-containing gas includes non-metal halide, metal halide, or a combination thereof, and the first film includes oxides, halides, or combinations thereof. The second halogen-containing gas includes hydrogen halide, nitrogen halide, ammonium halide, metal halide, carbon fluoride, alkyl halide, sulfur halide, or combinations thereof, and the second film includes metal halide.

In accordance with some embodiments of the present disclosure, the base structure further includes a gate protection portion which is disposed on the gate dielectric layer opposite to the gate electrode. Before the non-plasma etching process, the via opening extends through the gate protection portion to expose the surface region of the gate dielectric layer. A dielectric constant of the gate protection portion is lower than a dielectric constant of the gate dielectric layer.

In accordance with some embodiments of the present disclosure, a method for manufacturing a semiconductor structure includes: forming a base structure on a substrate, the base structure including channel portions which are vertically stacked and spaced apart from each other, a protection portion which is disposed on and spaced apart from an uppermost one of the channel portions, a gate dielectric layer which includes a first dielectric portion disposed beneath the protection portion and a second dielectric portion disposed around the channel portions, and a gate electrode disposed on the gate dielectric layer to fill spaces each of which is located between two corresponding adjacent ones of the channel portions and the protection portion; forming a via opening which penetrates the protection portion to terminate at the first dielectric portion; performing a non-plasma etching process on the first dielectric portion through the via opening until the via opening penetrates the first dielectric portion to expose a portion of the gate electrode; and forming a conductive cap portion on the portion of the gate electrode, so as to prevent the portion of the gate electrode from being exposed through the via opening. The non-plasma etching process and formation of the conductive cap portion are performed without breaking vacuum.

In accordance with some embodiments of the present disclosure, after the non-plasma etching process and before formation of the conductive cap portion, the method further includes: transferring the base structure from a first process chamber, in which the non-plasma etching process is conducted, to a second process chamber, in which the conductive cap portion is formed, under a pressure not greater than 0.1 torr.

In accordance with some embodiments of the present disclosure, the first process chamber and the second process chamber are different chambers in a same apparatus.

In accordance with some embodiments of the present disclosure, the non-plasma etching process includes alternately soaking the first dielectric portion in a first halogen-containing gas and a second halogen-containing gas, such that the first dielectric portion is removed atomic-layer-by-atomic-layer. A halogen element in the first halogen-containing gas is different from a halogen element in the second halogen-containing gas.

In accordance with some embodiments of the present disclosure, the conductive cap portion is formed by thermal chemical vapor deposition.

In accordance with some embodiments of the present disclosure, a metal-containing precursor gas and a reducing gas is used to form the conductive cap portion.

In accordance with some embodiments of the present disclosure, the protection portion has a dielectric constant that is lower than a dielectric constant of the gate dielectric layer.

In accordance with some embodiments of the present disclosure, an uppermost surface of the gate electrode is flush with an upper surface of the protection portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a base structure on a substrate, the base structure including a gate electrode and a gate dielectric layer covering the gate electrode;
forming a via opening extending from an upper surface of the base structure to expose the gate dielectric layer;
performing a non-plasma etching process on the gate dielectric layer through the via opening until the via opening penetrates the gate dielectric layer to expose a portion of the gate electrode; and
forming a conductive cap portion on the portion of the gate electrode, so as to prevent the portion of the gate electrode from being exposed through the via opening,
the non-plasma etching process and formation of the conductive cap portion being performed without breaking vacuum.

2. The method as claimed in claim 1, wherein
the non-plasma etching process includes at least one etch cycle, in which a first halogen-containing gas and a second halogen-containing gas are sequentially applied on the gate dielectric layer in such order, such that a surface region of the gate dielectric layer exposed to the via opening is removed after each cycle of the at least one etch cycle, and
a halogen element in the first halogen-containing gas is different from a halogen element in the second halogen-containing gas.

3. The method as claimed in claim 2, wherein the non-plasma etching process includes a gas soaking process.

4. The method as claimed in claim 2, wherein
the first halogen-containing gas includes hydrogen halide, nitrogen halide, ammonium halide, metal halide, carbon fluoride, alkyl halide, sulfur halide, or combinations thereof, and
the second halogen-containing gas includes non-metal halide, metal halide, or a combination thereof.

5. The method as claimed in claim 4, wherein
the first halogen-containing gas includes HF, NF₃, NH₄F, WF₆, CF₄, CHF₃, CH₃F, CH₂F₂, C₄F₈, C₄F₆, SF₆, or combinations thereof, and
the second halogen-containing gas includes BCl₃, MoCl₅, WCl₅, TiCl₄, or combinations thereof.

6. The method as claimed in claim 1, wherein the non-plasma etching process is performed at a pressure ranging from 0.1 torr to 10 torr.

7. The method as claimed in claim 1, wherein the conductive cap portion is formed by thermal CVD or thermal ALD.

8. The method as claimed in claim 1, wherein the conductive cap portion includes W, Ti, Mo, Ru, Ir, Re, Rh, Nb, or combinations thereof.

9. A method for manufacturing a semiconductor structure, comprising:
forming a base structure on a substrate, the base structure including a gate electrode and a gate dielectric layer covering the gate electrode;
forming a via opening extending from an upper surface of the base structure to expose a surface region of the gate dielectric layer;
performing a non-plasma etching process on the surface region of the gate dielectric layer through the via opening until the via opening penetrates the gate dielectric layer to expose a portion of the gate electrode, the non-plasma etching process including
subjecting the surface region of the gate dielectric layer to react with a first halogen-containing gas so as to form a first film, the first halogen-containing gas containing a first halogen,
performing an atomic layer clean treatment which includes
subjecting the first film to react with a second halogen-containing gas, so as to remove the first film and to form a second film different from the first film, the second halogen-containing gas containing a second halogen different from the first halogen, and
subjecting the second film to react with the first halogen-containing gas, so as to remove the second film and to form the first film, and
repeating the atomic layer clean treatment until the portion of the gate electrode is exposed through the via opening; and
forming a conductive cap portion on the portion of the gate electrode, so as to prevent the portion of the gate electrode from being exposed through the via opening,
the non-plasma etching process and formation of the conductive cap portion being performed without breaking vacuum.

10. The method as claimed in claim 9, wherein
the first halogen-containing gas includes hydrogen halide, nitrogen halide, ammonium halide, metal halide, carbon fluoride, alkyl halide, sulfur halide, or combinations thereof,
the first film includes metal halide,
the second halogen-containing gas includes non-metal halide, metal halide, or a combination thereof, and
the second film includes oxides.

11. The method as claimed in claim 9, wherein
the first halogen-containing gas includes non-metal halide, metal halide, or a combination thereof,
the first film includes oxides, halides, or combinations thereof,
the second halogen-containing gas includes hydrogen halide, nitrogen halide, ammonium halide, metal halide, carbon fluoride, alkyl halide, sulfur halide, or combinations thereof, and
the second film includes metal halide.

12. The method as claimed in claim 9, wherein
the base structure further includes a gate protection portion which is disposed on the gate dielectric layer opposite to the gate electrode,
before the non-plasma etching process, the via opening extends through the gate protection portion to expose the surface region of the gate dielectric layer, and
a dielectric constant of the gate protection portion is lower than a dielectric constant of the gate dielectric layer.

13. A method for manufacturing a semiconductor structure, comprising:
forming a base structure on a substrate, the base structure including
channel portions which are vertically stacked and spaced apart from each other,
a protection portion which is disposed on and spaced apart from an uppermost one of the channel portions,
a gate dielectric layer which includes a first dielectric portion disposed beneath the protection portion and a second dielectric portion disposed around the channel portions, and
a gate electrode disposed on the gate dielectric layer to fill spaces each of which is located between two corresponding adjacent ones of the channel portions and the protection portion;
forming a via opening which penetrates the protection portion to terminate at the first dielectric portion;
performing a non-plasma etching process on the first dielectric portion through the via opening until the via opening penetrates the first dielectric portion to expose a portion of the gate electrode; and
forming a conductive cap portion on the portion of the gate electrode, so as to prevent the portion of the gate electrode from being exposed through the via opening,
the non-plasma etching process and formation of the conductive cap portion being performed without breaking vacuum.

14. The method as claimed in claim 13, after the non-plasma etching process and before formation of the conductive cap portion, further comprising:
transferring the base structure from a first process chamber, in which the non-plasma etching process is conducted, to a second process chamber, in which the conductive cap portion is formed, under a pressure not greater than 0.1 torr.

15. The method as claimed in claim 14, wherein the first process chamber and the second process chamber are different chambers in a same apparatus.

16. The method as claimed in claim 13, wherein
the non-plasma etching process includes alternately soaking the first dielectric portion in a first halogen-containing gas and a second halogen-containing gas, such that the first dielectric portion is removed atomic-layer-by-atomic-layer, and
a halogen element in the first halogen-containing gas is different from a halogen element in the second halogen-containing gas.

17. The method as claimed in claim 13, wherein the conductive cap portion is formed by thermal chemical vapor deposition.

18. The method as claimed in claim 17, wherein a metal-containing precursor gas and a reducing gas is used to form the conductive cap portion.

19. The method as claimed in claim 13, wherein the protection portion has a dielectric constant that is lower than a dielectric constant of the gate dielectric layer.

20. The method as claimed in claim 13, wherein an uppermost surface of the gate electrode is flush with an upper surface of the protection portion.
